(19) United States
(12) Patent Application Publication
(10) Pub. No.: US 2008/0124192 A1
(43) Pub. Date: May 29, 2008

(54) Relay Station And Substrate Processing System Using Relay Station

(76) Inventor: Wataru Karasawa, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/793,686

(22) PCT Filed: Feb. 28, 2006
(86) PCT No.: PCT/JP06/03693

§ 371 Date: Jun. 22, 2007

(30) Foreign Application Priority Data
Mar. 1, 2005 (JP) 2005-056362

(51) Int. Cl. H01L 21/677

(52) U.S. Cl. 414/217; 414/411

(57) ABSTRACT

A relay station (10) has its interior determined as a substrate storing section (10a), and supporting sections (11) for supporting plural semiconductor wafers are formed on facing side walls of the substrate storing section. A substrate processing apparatus-side opening section (12) and a transfer apparatus-side opening section (13) are formed on both sides of the relay station (10), and these opening sections are provided with a substrate processing apparatus-side opening/closing mechanism (14) and a transfer apparatus-side opening/closing mechanism (15). A bottom plane (18) of the relay station (10) has a shape of a FOUP conforming to the SEMI standard and can be placed on a placing table for placing the FOUP.

### TECHNICAL FIELD

The present invention relates to a relay station, which is used for a substrate processing apparatus for processing substrates such as semiconductor wafers, and a substrate processing system using the relay station.

### BACKGROUND ART

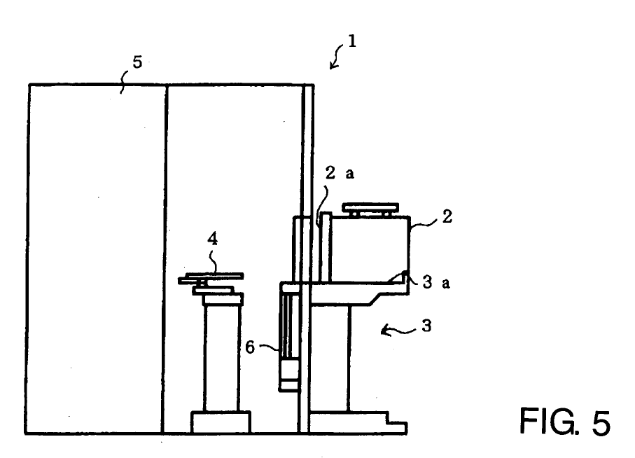

Conventionally, it is general that a substrate processing system for producing semiconductor devices or the like by processing substrates such as semiconductor wafers accommodates the semiconductor wafers in a transfer container (called as a cassette or a FOUP), which can accommodate plural (e.g., 25) semiconductor wafers, and transfers between processes. For example, as shown in FIG. 5, a substrate processing apparatus 1 is provided with a load port 3 as an interface for receiving a single or plural FOUPs 2 (or cassettes), and the load port 3 is provided with a single or plural placing sections 3a for placing the FOUPs 2 (or cassettes). And, the semiconductor wafers are taken out of the FOUPs 2 (or cassettes), which are placed on the placing sections 3a, by a transfer mechanism 4 and transferred to a processing section (configured of a processing chamber and the like) 5 for processing. The FOUP 2 is provided with an opening/closing mechanism (lid body) 2a for freely openably covering its front open section, and the substrate processing apparatus 1 is provided with a FOUP opener (lid body opening mechanism) 6 for opening/closing the opening/closing mechanism 2a.

For the above-described substrate processing apparatus, the mainstream has changed from a conventional batch-wafer processing apparatus for processing plural semiconductor wafers simultaneously to a single-wafer processing apparatus for processing semiconductor wafers one at a time. But, the transfer system (hereinafter referred to as the batch transfer) between processes using the cassettes or FOUPs above-described is an inefficient system having a long standby time because when the processing of a first semiconductor wafer is completed, the first semiconductor wafer is held in a standby condition and not transferred to the next process until the processing of a 25th semiconductor wafer is completed.

Therefore, construction of a system for transferring semiconductor wafers one at a time between processes is being studied in place of the conventional batch transfer. As such a system for transferring semiconductor wafers one at a time, for example, it is known that semiconductor wafers are transferred one at a time by a transfer conveyer, and a delivery device is disposed between the transfer conveyer and the substrate processing apparatus to deliver the semiconductor wafers (for example, Patent Document 1).

It is also studied to configure a system for transferring a semiconductor wafer using a transfer container such as a FOUP which can accommodate only one semiconductor wafer.

But, where the above-described single-substrate transfer apparatus for single- substrate transfer is used to configure a substrate processing system, it is necessary to provide every substrate processing apparatus with the delivery device for delivery of the substrate between the single-substrate transfer apparatus and the substrate processing apparatus. And, where the FOUP or the like which can accommodate only one semiconductor wafer is used to configure the substrate processing system, conventionally unused mechanisms such as a mechanism for opening/closing the lid of the FOUP, a mechanism for transferring the FOUP, and the like are required.

Therefore, where the conventionally-used substrate processing apparatus provided with the placing sections for placing cassettes or FOUPs in accordance with the conventional batch transfer using the cassettes or FOUPs is used to configure the substrate processing system, there are disadvantages that it is necessary to modify substantially the substrate processing apparatus, and considerable cost and time are required to reconfigure the system.

[Patent Document 1] Japanese Patent Laid-Open Application No. JP-A 2004-281474

### SUMMARY OF THE INVENTION

According to an aspect of the present invention, there is provided a relay station capable of configuring a substrate processing system for single-substrate transfer without substantially modifying a conventionally used substrate processing apparatus, and a substrate processing system using the relay station.

According to an aspect of the present invention, a relay station, which can be placed on a placing section of a substrate processing apparatus where a transfer container which can be transferred with plural substrates accommodated therein is placed, comprises a substrate storing section which is provided therein with supporting sections capable of supporting the substrates in a nearly horizontal state; a processing apparatus-side opening section which enables to deliver the substrates from the substrate processing apparatus to the substrate storing section and vice versa; and a transfer apparatus-side opening section which enables to deliver the substrates from the side of a transfer apparatus, which transfers the substrates to the substrate processing apparatus, to the substrate storing section and vice versa.

In the relay station according to the invention, the supporting sections can support the plural substrates in the form of shelves.

In the relay station according to the invention, a processing apparatus-side opening/closing mechanism for openably blocking the processing apparatus-side opening section is disposed.

In the relay station according to the invention, wherein a transfer apparatus-side opening/closing mechanism for openably blocking the transfer apparatus-side opening section is disposed.

In the relay station according to the invention, a fan filter unit for keeping a clean atmosphere within the substrate storing section is disposed.

A substrate processing system according to the invention, comprises a substrate processing apparatus which has placing sections, where a transfer container which can be transferred with plural substrates accommodated therein can be placed, and a processing section which performs prescribed processing on the substrates; a transfer apparatus which transfers unprocessed substrates to the substrate processing apparatus and transfers processed substrates from the substrate processing apparatus; and a relay station which has a substrate storing section which can be placed on the placing sections and is provided therein with supporting sections capable of supporting the substrates in a nearly horizontal state, a processing apparatus-side opening section capable of delivering the substrates from the substrate processing apparatus to the substrate storing section and vice versa, and a transfer apparatus-side opening section capable of delivering the substrates from the transfer apparatus for transferring the substrates to the substrate processing apparatus to the substrate storing section and vice versa.

In the substrate processing system according to the invention, wherein the supporting sections of the relay station can support the plural substrates in the form of shelves.

In the substrate processing system according to the invention, the relay station is provided with a processing apparatus-side opening/closing mechanism for openably blocking the processing apparatus-side opening section.

In the substrate processing system according to the invention, the substrate processing apparatus is provided with a drive mechanism for opening/closing the processing apparatus-side opening/closing mechanism.

In the substrate processing system according to the invention, the relay station is provided with a transfer apparatus-side opening/closing mechanism for openably blocking the transfer apparatus-side opening section.

In the substrate processing system according to the, invention, the transfer apparatus is provided with a drive mechanism for opening/closing the transfer apparatus-side opening/closing mechanism.

In the substrate processing system according to the invention, the transfer apparatus is configured to transport the substrates by a transfer vehicle.

In the substrate processing system according to the invention, the transfer vehicle is provided with a stocker capable of supporting the plural substrates and an on-vehicle transfer mechanism for delivery of the substrates between the stocker and the relay station.

In the substrate processing system according to the invention, the transfer vehicle is provided with a cover for keeping a clean atmosphere within it.

In the substrate processing system according to the invention, the transfer vehicle is configured to travel within a cover which keeps a clean atmosphere within it.

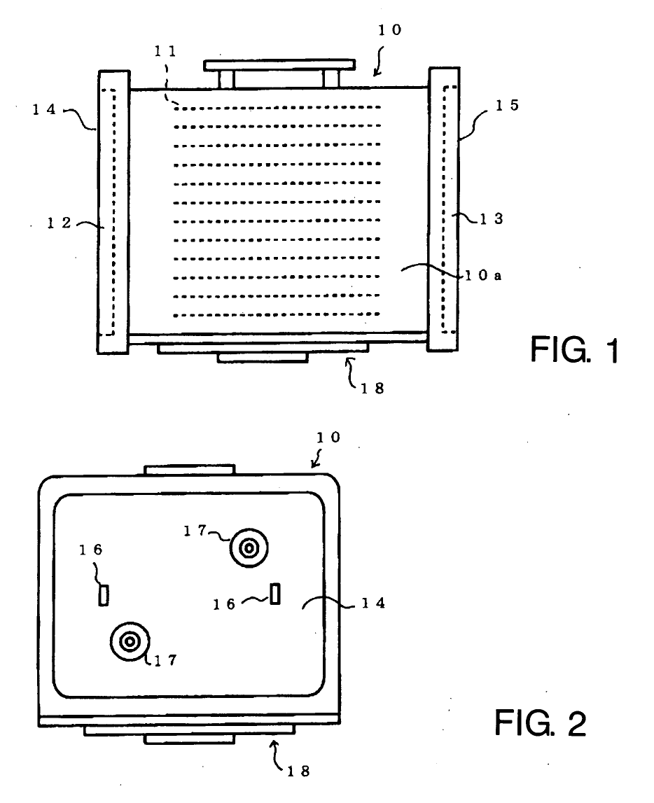

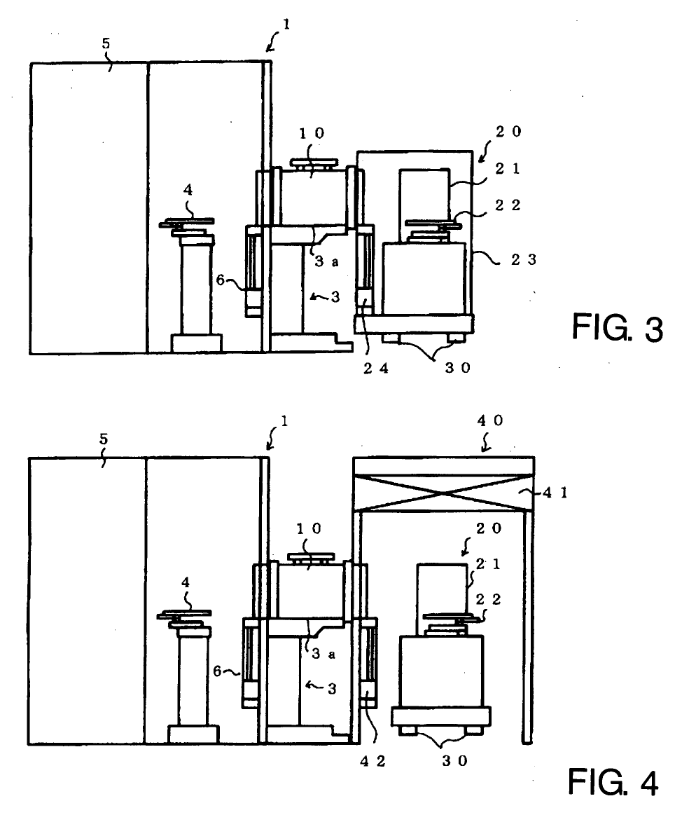

### BRIEF DESCRIPTION OF THE DRAWINGS

[FIG. 1] A side view showing a structure of the relay station according to an embodiment of the invention.

[FIG. 2] A front view of the relay station of FIG. 1.

[FIG. 3] A diagram showing a structure of the substrate processing system according to an embodiment of the invention.

[FIG. 4] A diagram showing a structure of the substrate processing system according to another embodiment of the invention.

[FIG. 5] A diagram showing a structure of a conventional substrate processing apparatus.

### BEST MODE FOR IMPLEMENTING THE INVENTION

Embodiments of the invention will be described with reference to the drawings. FIG. 1 shows a structure of the relay station according to an embodiment of the invention.

As shown in the drawing, a relay station 10 has a substantially same outside size as that of a FOUP used as a transfer container, and its interior is determined as a substrate storing section 10a, and its mutually faced inner side walls are provided with supporting sections (slots) 11 for supporting plural semiconductor wafers having a prescribed diameter (e.g., a diameter of 8 inches or 12 inches) in the form of shelves. The supporting sections 11 are required to be able to support one or more semiconductor wafers and designed to be able to support plural, for example, 25 semiconductor wafers, the same number as the FOUPs do.

The relay station 10 has two openings, one of them is a substrate processing apparatus-side opening section 12, and the other is a transfer apparatus-side opening section 13. In this embodiment, the substrate processing apparatus-side opening section 12 and the transfer apparatus-side opening section 13 are disposed to face each other, but the transfer apparatus-side opening section 13 may be disposed to face a direction orthogonal to the substrate processing apparatus-side opening section 12 in view of an access direction of the transfer apparatus.

The substrate processing apparatus-side opening section 12 is provided with a substrate processing apparatus-side opening/closing mechanism (lid body) 14, and the transfer apparatus-side opening section 13 is provided with a transfer apparatus-side opening/closing mechanism (lid body) 15. The substrate processing apparatus-side opening/closing mechanism 14 and the transfer apparatus-side opening/closing mechanism 15 are not indispensable and may be omitted. For example, in a case where the invention is applied to a system conventionally using an unsealed type cassette (open cassette), the substrate processing apparatus-side opening/closing mechanism 14 and the transfer apparatus-side opening/closing mechanism 15 are generally not disposed.

The substrate processing apparatus-side opening/closing mechanism 14 is provided with two engaging holes 16 having a prescribed shape formed at prescribed locations and two adsorbed portions 17 having a prescribed shape formed at prescribed locations as shown in FIG. 2. The engaging holes 16 and the adsorbed portions 17 comply with the SEMI (Semiconductor Equipment and Materials International) standard and can be opened/closed by a FOUP opener (a lid opening mechanism) conforming to the SEMI standard.

A transfer apparatus-side opening/closing mechanism 15 which is disposed on the transfer apparatus-side opening section 13 may be configured in the same manner as the above-described substrate processing apparatus-side opening/closing mechanism 14, and because it is opened/closed on the side of the transfer apparatus, another opening/closing mechanism may be used in accordance with the lid opening mechanism disposed on the transfer apparatus. Besides, the shape and size of the transfer apparatus-side opening section 13 may be different from those of the substrate processing apparatus-side opening section 12 if it is possible to access the inside of the substrate storing section 10a from the side of the transfer apparatus to load/unload the semiconductor wafers.

The relay station 10 has a bottom face 18 which has a shape of the FOUP conforming to the SEMI standard. Thus, it is configured such that the relay station 10 can be placed on a placing table for placing the FOUP thereon.

If necessary, the relay station 10 may be provided with a fan filter unit (FFU) for providing a clean atmosphere within the substrate storing section 10a.

FIG. 3 shows a structure of one embodiment of a substrate processing system using the relay station 10 configured as described above. As shown in the drawing, the relay station 10 configured as described above has the substrate processing apparatus-side opening section 12 disposed to face the substrate processing apparatus 1 on the placing sections 3a of the load port 3 of the substrate processing apparatus 1 in accordance with the batch transfer using the FOUPs as the transfer container in the same manner as shown in FIG. 5.

And, the substrate processing apparatus-side opening/closing mechanism 14 disposed on the substrate processing apparatus-side opening section 12 is opened/closed by the FOUP opener (lid body opening mechanism) 6 disposed on the substrate processing apparatus 1. With the substrate processing apparatus-side opening/closing mechanism 14 in an open state, unprocessed semiconductor wafers are transferred by the transfer mechanism 4, which is disposed in the substrate processing apparatus 1, from the relay station 10 to a processing section (configured of a processing chamber and the like for performing prescribed processing such as film forming, etching and the like) 5, and the processed semiconductor wafers are transferred from the processing section into the relay station 10.

The substrate processing apparatus 1 is mostly provided with plural (for example, two) placing sections 3a. For example, the FOUP in which the unprocessed semiconductor wafers are accommodated is disposed on one of the placing sections 3a, and the FOUP in which the processed semiconductor wafers are accommodated is disposed on the other of the placing sections 3a. In a case where the substrate processing system is configured as in this embodiment, the plural placing sections 3a each may be provided with the relay station 10 or only one of the placing sections 3a may be provided with the relay station 10.

Meanwhile, a transfer path along which a transfer vehicle 20 travels is disposed on the side of the transfer apparatus-side opening section 13 of the relay station 10, and the transfer vehicle 20 is connected to the transfer apparatus-side opening section 13 to perform delivery of the semiconductor wafers. In this embodiment, the transfer vehicle 20 is an automatic transport vehicle (RGV (Rail Guided Vehicle)) which travels along rails 30. As the transfer vehicle 20, an automatic transport vehicle (AGV (Automatic Guided Vehicle)) can also be used.

The transfer vehicle 20 is provided with a stocker 21 capable of accommodating plural semiconductor wafers, and an on-vehicle transfer mechanism 22 for delivery of the semiconductor wafers between the stocker 21 and the substrate processing apparatus 1. And, the stocker 21 and the on-vehicle transfer mechanism 22 are covered with a cover 23 for keeping a clean atmosphere in the interior. And, a lid body opening mechanism 24 for opening/closing the transfer apparatus-side opening/closing mechanism 15 is disposed on a part of the cover 23 faced to the transfer apparatus-side opening section 13 of the relay station 10.

The transfer vehicle 20 travels along the rails 30 with the semiconductor wafers accommodated in the stocker 21 to transfer between processes (between the substrate processing apparatus 1 and another substrate processing apparatus), docks with the transfer apparatus-side opening section 13 of the relay station 10, opens the transfer apparatus-side opening/closing mechanism 15 by the lid body opening mechanism 24, and delivers the semiconductor wafers by the on-vehicle transfer mechanism 22.

As described above, the relay station 10 and the substrate processing system using the relay station 10 of his embodiment can configure a system based on the single-substrate transfer using the transfer vehicle 20 with the relay station 10 disposed on the placing sections 3a for placing the FOUPs of the substrate processing apparatus 1 conforming to the batch transfer using the FOUPs. Therefore, the system based on the single-substrate transfer can be configured easily at a low cost without substantially modifying the conventionally used substrate processing apparatus 1. The substrate processing apparatus which is originally designed on the assumption that the single-substrate transfer system is configured can directly deliver the semiconductor wafers by the transfer vehicle 20 without using the relay station 10. Thus, a substrate processing system having both such a new substrate processing apparatus and the substrate processing apparatus 1 conforming to the conventional batch transfer shown in FIG. 3 can also be configured easily by using the relay station 10.

By allowing accommodation of plural semiconductor wafers into the relay station 10 and also into the stocker 21 of the transfer vehicle 20, an occurrence of a situation that the transfer by the transfer vehicle 20 becomes late when the processing speed of the substrate processing apparatus 1 is fast and the time required for processing is short is prevented, and a highly efficient substrate processing system can be configured. In such a case, even the single-substrate transfer performs transfer by delivering plural (for example, two or three) semiconductor wafers at a time between the transfer vehicle 20 and the substrate processing apparatus 1.

FIG. 4 shows a structure of the substrate processing system according to another embodiment. In this embodiment, a cover 40 for keeping a clean atmosphere within it is disposed along the transfer path along which the transfer vehicle 20 travels, and the transfer vehicle 20 travels within the cover 40. Therefore, the transfer vehicle 20 is not provided with the cover 23 for covering the stocker 21 and the on-vehicle transfer mechanism 22 shown in FIG. 3. And, a fan filter unit (FFU) 41 for keeping a clean atmosphere within the cover 40 is disposed on the ceiling of the cover 40.

In this embodiment, a lid body opening mechanism 42 for opening/closing the transfer apparatus-side opening/closing mechanism 15 is disposed on the cover 40.

This substrate processing system communicates the substrate processing apparatus 1, which is kept to have a clean atmosphere within it, with the interior of the cover 40 by means of the relay station 10. Therefore, the relay station 10 is not required to have the processing apparatus-side opening/closing mechanism 14 and the transfer apparatus-side opening/closing mechanism 15, and the lid body opening mechanism 42 can also be omitted.

The above-configured substrate processing system can easily configure a system based on the single-substrate transfer at a low cost and can provide the same effects as those of the above-described substrate processing system shown in FIG. 3 without substantial modification of the conventionally used substrate processing apparatus 1.

It was described in the above embodiment that the substrate processing apparatus 1 was configured in conformity with the batch transfer based on the FOUPs. But the invention can also be applied to a case configured in conformity with the batch transfer based on another transfer container, for example, a cassette.

### INDUSTRIAL APPLICABILITY

The relay station and the substrate processing system using the relay station according to the invention can be used in the field of producing semiconductor devices and the like. Therefore, they have industrial applicability.

What is claimed is:

1. A relay station, configured to be placed on a placing section of a substrate processing apparatus where a transfer container which can be transferred with plural substrates accommodated therein is placed, comprising:
a substrate storing section which is provided therein with supporting sections capable of supporting the substrates in a nearly horizontal state;
a processing apparatus-side opening section which enables to deliver the substrates from the substrate processing apparatus to the substrate storing section and vice versa; and
a transfer apparatus-side opening section which enables to deliver the substrates from the side of a transfer apparatus, which transfers the substrates to the substrate processing apparatus, to the substrate storing section and vice versa.

2. The relay station according to claim 1, wherein the supporting sections can support the plural substrates in the form of shelves.

3. The relay station according to claim 1, wherein a processing apparatus-side opening/closing mechanism for openably blocking the processing apparatus-side opening section is disposed.

4. The relay station according to claim 1, wherein a transfer apparatus-side opening/closing mechanism for openably blocking the transfer apparatus-side opening section is disposed.

5. The relay station according to claim 1, wherein a fan filter unit for keeping a clean atmosphere within the substrate storing section is disposed.

6. A substrate processing system, comprising:
a substrate processing apparatus having placing sections, where a transfer container which can be transferred with plural substrates accommodated therein can be placed, and a processing section which performs prescribed processing on the substrates;
a transfer apparatus which transfers unprocessed substrates to the substrate processing apparatus and transfers processed substrates from the substrate processing apparatus; and
a relay station which has a substrate storing section which can be placed on the placing sections and is provided therein with supporting sections capable of supporting the substrates in a nearly horizontal state, a processing apparatus-side opening section capable of delivering the substrates from the substrate processing apparatus to the substrate storing section and vice versa, and a transfer apparatus-side opening section capable of delivering the substrates from the transfer apparatus for transferring the substrates to the substrate processing apparatus to the substrate storing section and vice versa.

7. The substrate processing system according to claim 6, wherein the supporting sections of the relay station can support the plural substrates in the form of shelves.

8. The substrate processing system according to claim 6, wherein the relay station is provided with a processing apparatus-side opening/closing mechanism for openably blocking the processing apparatus-side opening section.

9. The substrate processing system according to claim 8, wherein the substrate processing apparatus is provided with a drive mechanism for opening/closing the processing apparatus-side opening/closing mechanism.

10. The substrate processing system according to claim 6, wherein the relay station is provided with a transfer apparatus-side opening/closing mechanism for openably blocking the transfer apparatus-side opening section.

11. The substrate processing system according to claim 10, wherein the transfer apparatus is provided with a drive mechanism for opening/closing the transfer apparatus-side opening/closing mechanism.

12. The substrate processing system according to claim 6, wherein the transfer apparatus is configured to transport the substrates by a transfer vehicle.

13. The substrate processing system according to claim 12, wherein the transfer vehicle is provided with a stocker capable of supporting the plural substrates and an on-vehicle transfer mechanism for delivery of the substrates between the stocker and the relay station.

14. The substrate processing system according to claim 13, wherein the transfer vehicle is provided with a cover for keeping a clean atmosphere within it.

15. The substrate processing system according to claim 13, wherein the transfer vehicle is configured to travel within a cover which keeps a clean atmosphere within it.
